(19) United States
(12) Patent Application Publication
(10) Pub. No.: US 2010/0315266 A1
(43) Pub. Date: Dec. 16, 2010

(54) PREDICTIVE INTERFACES WITH USABILITY CONSTRAINTS

(75) Inventors: Asela J. Gunawardana, Seattle, WA (US); Timothy S. Paek, Sammamish, WA (US); Christopher A. Meek, Kirkland, WA (US)

Correspondence Address: MICROSOFT CORPORATION, ONE MICROSOFT WAY, REDMOND, WA, 98052, US

(73) Assignee: Microsoft Corporation, Redmond, WA (US)

(21) Appl. No.: 12/484,532

(22) Filed: Jun. 15, 2009

(51) Int. Cl. H03K 17/94

(52) U.S. Cl. 341/22

(57) ABSTRACT

A “Constrained Predictive Interface” uses predictive constraints to improve accuracy in user interfaces such as soft keyboards, pen interfaces, multi-touch interfaces, 3D gesture interfaces, EMG based interfaces, etc. In various embodiments, the Constrained Predictive Interface allows users to take any desired action at any time by taking into account a likelihood of possible user actions in different contexts to determine intended user actions. For example, to enable a virtual keyboard interface, various embodiments of the Constrained Predictive Interface provide key “sweet spots” as predictive constraints that allow the user to select particular keys regardless of any probability associated with the selected or neighboring keys. In further embodiments, the Constrained Predictive Interface provides hit target resizing via various piecewise constant touch models in combination with various predictive constraints. In general, hit target resizing provides dynamic real-time virtual resizing of one or more particular keys based on various probabilistic criteria.

### BACKGROUND

1. Technical Field

A “Constrained Predictive Interface” provides various techniques for using predictive constraints in a source-channel model to improve the usability, accuracy, discoverability, etc. of user interfaces such as soft keyboards, pen interfaces, multi-touch interfaces, 3D gesture interfaces, myoelectric or EMG based interfaces, etc.

2. Related Art

Conventional “single-tap” key entry systems are referred to as “predictive” because they predict the user's intended word, given the current sequence of keystrokes. In general, conventional predictive interfaces ignore any ambiguity between characters upon entry to enter a character with only a single tap of the associated key. However, because multiple letters may be associated with the key-tap, the system considers the possibility of extending the current word with each of the associated letters. Single-tap entry systems are surprisingly effective because, after the first few key-taps of a word, there are usually relatively few words matching that sequence of taps. However, despite improved performance, single-tap systems are still subject to ambiguity at the word level. Various techniques exist for using contextual information of words to aid the overall prediction process.

Predictive virtual keyboards and the like have been implemented in a number of space-limited environments, such as the relatively small display area of mobile phones, PDA, media players, etc. For example, one well-known mobile phone provides a virtual keyboard (rendered on a touch-screen display) that uses a built-in dictionary to predict words while the user is typing those words. Using these predictions, the keyboard readjusts the size of “tap zones” of letters, making the ones that are most likely to be selected by the user larger while making the tap zones of letters that are less likely to be typed smaller. Note that the displayed keys themselves do not change size, just the tap zones corresponding to physical regions that allow those keys to be selected by the user.

More specifically, conventional solutions in this field often use a “source-channel predictive model” to implement a predictive user interface (UI). In general, the predictive features of these techniques are implemented by using a statistical model that models the likelihood that users would type different sequences of keys (a source model or language model). This source model is then combined with another statistical model that models the likelihood that a user touching different soft keys will generate different digitizer detection patterns (i.e., a channel model or touch model). In the case of a virtual keyboard, the digitizer typically outputs an (x, y) coordinate pair for each touch or tap, with that coordinate then being used to identify or select a particular key based on the tap zone corresponding to the (x, y) coordinate. In other words, a source-channel model has components including a source model and a channel model.

One problem with some of the conventional source-channel predictive models that are used to enable virtual keyboards is that in some cases, overly strict predictive models actually prevent the user from selecting particular keys, even if the user wants to select a particular key. For example, one well-known mobile phone, which provides a touch-screen based virtual keyboard, will not allow the user to type the letter sequence “Steveb” since the predictive model assumes that the user is actually attempting to type the name “Steven” (since the “n” key is adjacent to the “b” key on a standard QWERTY style keyboard). The problem here is that that in the case that the user is actually trying to type an email address, such as “steveb@microsoft.com” the aforementioned mobile phone predictive model will not allow this address to be typed.

Additional examples of the overly strict predictive model of the aforementioned mobile phone include not allowing the user to deviate from typing any character surrounding the last character of various words such as, for example, “know”, “time”, “spark”, “quick”, “build”, “split”, etc. In other words, the tap zones of letters surrounding the last letter of such words is either eliminated or sufficiently covered by the tap zone of the letter expected by the conventional source-channel predictive model such that the user simply cannot select the tap zone for any other letter. An example is that in the case of the word “know”, the user is prevented by selecting the characters surrounding the “w” key (on a qwerty keyboard) such that the user is specifically prevented from selecting either the “q” (left), or the “e” (right) key surrounding the “w” key. This is a problem if the user is typing an alias or a proper noun, such as the company name “Knoesis”.

Another conventional “soft keyboard” approach introduces the concept of fuzzy boundaries for the various keys. For example, when a user presses a spot between the “q” and the “w” keys, the actual letter “pressed” or tapped by the user is automatically determined based on the precise location where the soft keyboard was actuated, the sequence of letters already determined to have been typed by the user, and/or the typing speed of the user. In other words, this soft keyboard provides a predictive keyboard interface that predicts at least one key within a sequence of keys pressed by the user that is only a partial function of the physical location tapped or pressed by the user. Further, in some cases, this soft keyboard will render predicted keys differently from other keys on the keyboard. For example, the predicted keys may be larger or highlighted differently on the soft keyboard as compared to the other keys, making them more easily typed by a user as compared to the other keys.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In general, a “Constrained Predictive Interface,” as described herein, uses a “source-channel predictive model” to implement predictive user interfaces (UI). However, in contrast to conventional source-channel predictive models, the Constrained Predictive Interface further uses various predictive constraints on the overall source-channel model (either as a whole, or on either the source model or the channel model individually) to improve UI characteristics such as accuracy, usability, discoverability, etc. This use of predictive constraints improves user interfaces such as soft or virtual keyboards, pen interfaces, multi-touch interfaces, 3D gesture interfaces, myoelectric or EMG based interfaces, etc. Note that the terms “soft keyboard” and “virtual keyboard” are used interchangeably herein to refer to various non-physical keys or keyboards such as touch-screen based keyboards having one or more keys rendered on a display device, laser or video projection based keyboards where an image of keys or a keyboard is projected onto a surface, or any other similar keyboard lacking physical keys that are depressed by the user to enter or select that key.

More specifically, in various embodiments, the predictive constraints limit the source-channel model by forcing specific user actions regardless of any current user input context when conditions corresponding to specific predictive constraints are met by user input received by the Constrained Predictive Interface. In other words, in various embodiments, the Constrained Predictive Interface ensures that a user can take any desired action at any time by taking into account a likelihood of possible user actions in different contexts to determine intended user actions (e.g., intended user input or command) relative to the additional predictive constraints on either the channel model, the source model, or the overall source-channel predictive model.

For example, in the context of virtual keyboard interfaces, various embodiments of the Constrained Predictive Interface use predictive constraints such as key “sweet spots” within an overall “hit target” defining each key. In general, selection of the overall hit target of a particular key may return that key, or some neighboring key, depending upon the probabilistic context of the user input based on an evaluation of that input by the source-channel model. However, selection of the sweet spot of a particular key will return that key, regardless of the probabilistic or predictive context associated with the overall source-channel model. In other words, in a soft or virtual keyboard, the hit target of each key corresponds to some physical region in proximity to each key that may return that key when some point within that physical region is touched or otherwise selected by the user, while the sweet spot within that hit target will always return that key (unless additional limitations or exceptions are used in combination with the constraints).

In related embodiments, predictive hit target resizing provides dynamic real-time virtual resizing of one or more particular keys based on various probabilistic criteria. Consequently, hit target resizing makes it more likely that the user will select the intended key, even if the user is not entirely accurate when selecting a position corresponding to the intended key. Further, in various embodiments, hit target resizing is based on various probabilistic piecewise constant touch models, as specifically defined herein. Note that hit target resizing does not equate to a change in the rendered appearance of keys. However, in various embodiments of the Constrained Predictive Interface, rendered keys are also visually increased or decreased in size depending on the context.

In further embodiments, a user adjustable or automatic “context weight” is applied to either the source (or language) model, to the channel (or touch) model, or to a combination thereof. For example, in various embodiments of the automatic case, the context weight, and which portion of source-channel model that weight is applied to, is a function of one or more observed user input behaviors or “contexts”, including factors such as typing speed, latency between keystrokes, input scope, keyboard size, device properties, etc., which depend on the particular user interface type being enabled by the Constrained Predictive Interface. The context weight controls the influence of the predictive intelligence of the source or channel model on the overall source-channel model.

For example, in the case of a virtual keyboard, as the context weight on the touch model is increased relative to the language model, the influence of the predictive intelligence of the touch model on the overall language-touch model of the virtual keyboard becomes more dominant. Note also that in various embodiments, the context weight is used to limit the effects of the predictive constraints on the source or channel model (since the influence of the predictive intelligence of those models on the overall source-channel model is limited by the context weight). However, in related embodiments, the predictive constraints on either component of the source-channel model are not influenced or otherwise limited by the of the optional context weight.

In view of the above summary, it is clear that the Constrained Predictive Interface described herein provides various techniques for applying predictive constraints to a source-channel predictive model to improve characteristics such as accuracy, usability, discoverability, etc. in a variety of source-channel based predictive user interfaces. Examples of such predictive interfaces include, but are not limited to soft or virtual keyboards, pen interfaces, multi-touch interfaces, 3D gesture interfaces, myoelectric or EMG based interfaces, etc. In addition to the just described benefits, other advantages of the Constrained Predictive Interface will become apparent from the detailed description that follows hereinafter when taken in conjunction with the accompanying drawing figures.

### DESCRIPTION OF THE DRAWINGS

The specific features, aspects, and advantages of the claimed subject matter will become better understood with regard to the following description, appended claims, and accompanying drawings where:

FIG. 1 provides an exemplary architectural flow diagram that illustrates program modules for implementing various embodiments of the Constrained Predictive Interface, as described herein.

FIG. 2 illustrates an example of “Qwerty” Keyboard “hit targets” (illustrated by broken lines around each key) with no hit target resizing (i.e., hit target intelligence turned off), as described herein

FIG. 3 illustrates an example of a hit target (illustrated by broken lines) for the letter “S” that encompasses several neighboring “sweet spots” (illustrated by solid regions within each key), as described herein.

FIG. 4 illustrates an example of a hit target (illustrated by broken lines) for the letter “S” that does not encompass any neighboring “sweet spots” (illustrated by solid regions within each key), as described herein.

FIG. 5 illustrates an example of conventional hit target geometries where the output will change from a first key, to a second key, then back to the first key while the user moves along a continuous straight-line path, as described herein.

FIG. 6 illustrates the use of convex hit targets for keys in a soft or virtual keyboard, as described herein.

FIG. 7 illustrates an example of hit targets (illustrated by broken lines) in a “row-by-row” touch model, as described herein.

FIG. 8 illustrates an example of nested hit targets (illustrated by broken lines) surrounding a key “sweet spot” (illustrated by a solid region) for the “S” key for a “piecewise constant touch model”, as described herein.

FIG. 9 is a general system diagram depicting a simplified general-purpose computing device having simplified computing and I/O capabilities for use in implementing various embodiments of the Constrained Predictive Interface, as described herein.

### DETAILED DESCRIPTION OF THE EMBODIMENTS

In the following description of the embodiments of the claimed subject matter, reference is made to the accompanying drawings, which form a part hereof, and in which is shown by way of illustration specific embodiments in which the claimed subject matter may be practiced. It should be understood that other embodiments may be utilized and structural changes may be made without departing from the scope of the presently claimed subject matter.

1.0 Introduction

In general, a “Constrained Predictive Interface,” as described herein, provides various techniques for using predictive constraints in combination with a source-channel predictive model to improve accuracy in a variety of user interfaces, including for example, soft or virtual keyboards, pen interfaces, multi-touch interfaces, 3D gesture interfaces, myoelectric or EMG based interfaces, etc. More specifically, the Constrained Predictive Interface provides various embodiments of a source-channel predictive model with various predictive constraints applied to the source-channel model (either as a whole, or on either the source model or the channel model individually) to improve UI characteristics such as accuracy, usability, discoverability, etc.

Note that the concept of source-channel predictive models for user interfaces is known to those skilled in the art, and will not be described in detail herein. However, the concept of applying additional predictive constraints to the channel model of the overall source-channel predictive model to enable the Constrained Predictive Interface will be described in detail herein. Further, it should also be noted that the terms “soft keyboard” and “virtual keyboard” are used interchangeably herein to refer to various non-physical keys or keyboards such as touch-screen based keyboards having one or more keys rendered on a touch-screen display device, laser or video projection based keyboards where an image of keys or a keyboard is projected onto a surface in combination with the use of various sensor devices to monitor user finger position, or any other similar keyboard lacking physical keys that are depressed by the user to enter or select that key. In addition, it should also be understood that that soft and virtual keyboards are known to those skilled in the art, and will not be specifically described herein except as they are improved via the Constrained Predictive Interface.

For example, in the case of a soft or virtual keyboard, the source model is represented by a probabilistic or predictive language model while the channel model is represented by a probabilistic or predictive touch model to construct a predictive language-touch model. In this case, the language model provides a predictive model of probabilistic user key input sequences, based on language, spelling, grammar, etc. Further, the touch model provides a predictive model for generating digitizer detection patterns corresponding to user selected coordinates relative to the soft keyboard. These coordinates then map to particular keys, as a function of the language model. In other words, the language and touch models are combined to produce a probabilistic language-touch model of the soft keyboard. However, in contrast to conventional language-touch models (or other source-channel predictive models), the touch (or channel) model is further constrained by applying predictive constraints to the touch model. The result is a source-channel predictive model having predictive constraints on the channel model to improve the accuracy of the overall source-channel predictive model.

1.1 System Overview

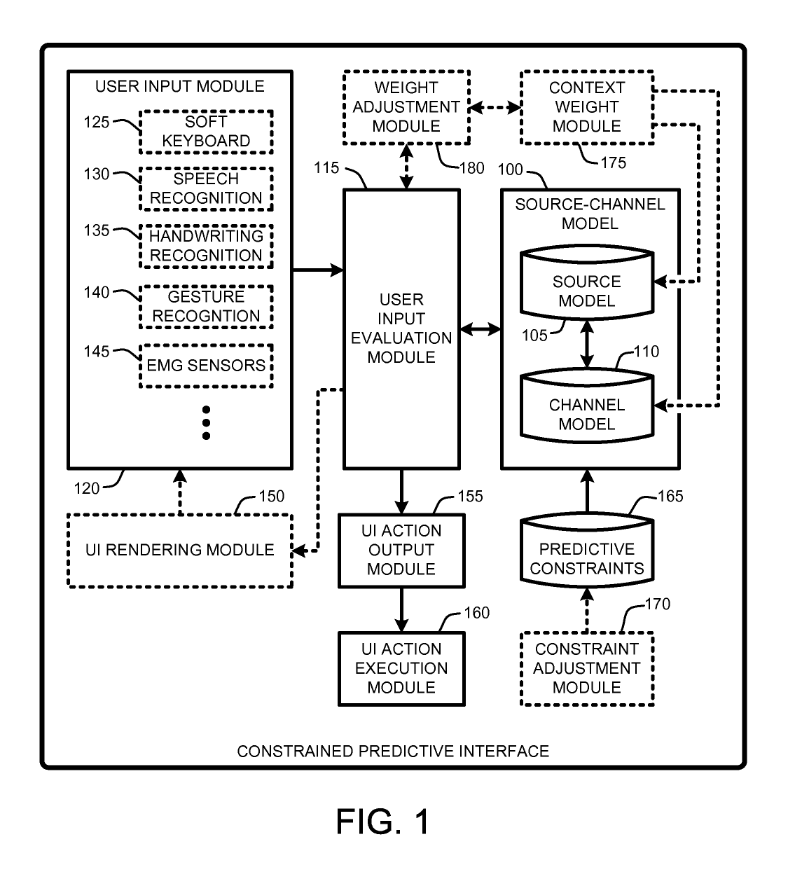

As noted above, the “Constrained Predictive Interface,” provides various techniques for applying predictive constraints on the channel model to improve accuracy in a variety of source-channel based predictive UIs, including for example, soft or virtual keyboards, pen interfaces, multi-touch interfaces, 3D gesture interfaces, myoelectric or EMG based interfaces, etc. The processes summarized above are illustrated by the general system diagram of FIG. 1.

In particular, the system diagram of FIG. 1 illustrates the interrelationships between program modules for implementing various embodiments of the Constrained Predictive Interface, as described herein. Furthermore, while the system diagram of FIG. 1 illustrates a high-level view of various embodiments of the Constrained Predictive Interface, FIG. 1 is not intended to provide an exhaustive or complete illustration of every possible embodiment of the Constrained Predictive Interface as described throughout this document.

In addition, it should be noted that any boxes and interconnections between boxes that may be represented by broken or dashed lines in FIG. 1 represent alternate embodiments of the Constrained Predictive Interface described herein. Further, it should also be noted that that any or all of these alternate embodiments, as described below, may be used in combination with other alternate embodiments that are described throughout this document.

In general, as illustrated by FIG. 1, the processes enabled by the Constrained Predictive Interface begin operation by defining a source-channel model 100 of the user interface (e.g., soft or virtual keyboards, pen interfaces, multi-touch interfaces, 3D gesture interfaces, myoelectric or EMG based interfaces, etc.). The source-channel model 100 includes a source model 105 and a channel model 110. As noted above, in the case of a soft or virtual keyboard, the source model 105 is represented by a language model, while the channel model 110 is represented by a touch model. However, it should be understood that the specific model types for the source model 105 and the channel model 110 are dependent upon the particular type of UI being enabled by the Constrained Predictive Interface.

Once the source-channel model 100 has been defined for the particular user interface being enabled by the Constrained Predictive Interface, a user input evaluation module 115 receives a user input from a user input module 120. As noted above, the user input evaluation module 115 queries the source-channel model 100 with the input received from the user input module 120 to determine what that user input represents (e.g., a particular key of a soft keyboard, a particular gesture for a gesture-based UI, etc.). As noted above, Constrained Predictive Interface can be used to enable any user interface that is modeled using a source-channel based prediction system. Examples of such interfaces include soft keyboards 125, speech recognition 130 interfaces, handwriting recognition 135 interfaces, gesture recognition 140 interfaces, EMG sensor 145 based interfaces, etc.

In the case of virtual UIs such as a soft keyboard, for example, where the keyboard is either displayed on a touch screen or rendered on some surface or display device, a UI rendering module 150 renders the UI so that the user can see the interface in order to improve interactivity with that UI. In various embodiments, “hit targets” associated with the keys are expanded or contracted depending on the context. In general, in the case of a soft or virtual keyboard (or other button or key-based UI), the hit target of each key or button corresponds to some physical region in proximity to each key that will return that key when some point within that physical region is touched or otherwise selected by the user. See Section 2.1 and Section 2.2 for further discussion on “hit-target” resizing (also discussed herein as “resizable hit targets”).

Further, in related embodiments corresponding to key-based UI's such as soft keyboards or virtual button based interfaces, key resizing is used such that various keys or buttons of the UI visually expand or contract in size depending upon the current probabilistic context of the user input. For example, assuming that the current context makes it more likely that the user will type the letter “U” (i.e., the user has just typed the letter “Q”), the representation of the letter “U” in the rendered soft keyboard will be increased in size (while surrounding keys may also be decreased in size to make room for the expanded “U” key). In such cases, the UI rendering module 150 receives key or button resizing instruction input (as a function of the current input context) from the user input evaluation module 115 that in turn queries the source-channel model 100 to determine the current probabilistic context of the user input for making resizing decisions. In addition, it should be understood that both hit target resizing and key resizing may be combined to create various hybrid embodiments of the Constrained Predictive Interface, as described herein.

Once the user input evaluation module 115 determines the intended user input via the source-channel model 100, the user input evaluation module passes that information to a UI action output module 155 that simply sends the intended user input to a UI action execution module 160 for command execution. For example, if the intended user determined by the user input evaluation module 115 input is a typed “U” key, the UI action output module 155 sends the “U” key to the UI action execution module 160 which then processes that input using convention techniques (e.g., inserting the “U” key into a text document being typed by the user).

As noted above, the Constrained Predictive Interface uses various predictive constraints 165 on the channel model 110 (i.e., the touch model in the case of a soft or virtual keyboard) in the source-channel predictive model to ensure that particular usability constraints will be honored by the system, regardless of the context. More specifically, as described in Section 2.5, in various embodiments of the Constrained Predictive Interface, one or more a priori constraints are used to limit the channel model 110 in order to improve the user experience. For example, in the case of soft or virtual keyboards, these a priori predictive constraints 165 include concepts such as, for example, “sweet spots” and “convex hit targets.”

Considering the case of a virtual keyboard, “sweet spots” are defined by a physical region or area located in or near the center of each rendered key that returns that key, regardless of the probabilistic or predictive context returned by the source-channel model 100. Similarly, in the case of a virtual keyboard, the use of convex hit targets changes the shape (and typically size) of the hit targets for one or more of the keys as a function of the current probabilistic context of the user input. However, it should be understood that as described in Sections 2.5 and 2.8, the specific type of predictive constraint 165 applied to the touch model 110 will depend upon the particular type of UI (i.e., UI's based on virtual keyboards, speech, handwriting, gestures, EMG sensors, etc. will use different predictive constraints).

In various related embodiments, a constraint adjustment module 170 is provided to allow either or both manual or automatic adjustments to the predictive constraints. For example, in the case of a soft or virtual keyboard, the size of the sweet spot associated with one or more specific keys can be increased or decreased, either automatically or by the user, via the constraint adjustment module 170. Similarly, in the case of a handwriting-based UI, where the “sweet-spot” constraint on the channel model is any pattern, within some fixed threshold of an exemplary pattern, that is recognized as a corresponding character or word, regardless of any probabilistic context associated with the corresponding source-channel model 100. Therefore, in this case, the constraint adjustment module 170 will be used to adjust the fixed threshold around the exemplary pattern within which a particular character or word is always recognized, regardless of the probabilistic context (unless additional limitations or exceptions are used in combination with the constraints).

In further embodiments (see Section 2.4), the concept of a “context weight” is applied to either the source model 105 or the channel model 110, or to a combination of both models. In particular, while predictive models such as the source-channel model 100 are useful for improving the accuracy of various UIs, overly strict predictive models can actually prevent the user from achieving particular inputs (such as selecting particular keys of a virtual keyboard), regardless of the user intent. Therefore, to address such issues, in various embodiments, a context weight module 175 allows the user to adjust a weight, α, typically ranging from 0% to 100% (but can be within any desired range) when weighting the source model 105, or typically from 100% and up (but can be within any desired range) when weighting the channel model 110. In general, at a context weight of 0% on the source model, the predictive intelligence of the source model 105 is eliminated, while at 100% weighting, the predictive intelligence of the weighted source model behaves as if it is not weighted. Similarly, as the weight on the channel model 110 is increased above 100%, the predictive influence of the channel model becomes more dominant over that of the source model 105.

For example, in the case of a soft or virtual keyboard with weighting of the language model (i.e., the source model 105), it is useful for the hit targets for each key to correspond to the boundaries of each of the rendered keys when the context weight is set at or near 0% on the language model. Note that causing keys to correspond to the boundaries of each of the rendered keys is the same result that would be obtained if no predictive touch model were used in implementing the virtual keyboard. In other words, pressing anywhere in the rendered boundary of any key will return that key in this particular case. Conversely, where the context weight on the touch model is increased above 100%, the predictive influence of the touch model (such as, for example, context-based hit target resizing) will increase, with the result that key hot targets may not directly correspond to the rendered keys.

In related embodiments, a weight adjustment module 180 automatically adjusts the context weight on either or both the source model 105 or the channel model 110 as a function of various factors (e.g., user typing speed, latency between keystrokes, input scope, keyboard size, device properties, etc.) as determined by the user input evaluation module 115. In addition, in various embodiments, the weight adjustment module 180 also makes a determination of which of the models (i.e., the source model 105 or the channel model 110) is to be weighted via the use of the context weight. See Section 2.4 for additional details regarding use of the context weight to modify the predictive influence of either the source model 105 or the channel model 110.

2.0 Operational Details of the Constrained Predictive Interface

The above-described program modules are employed for implementing various embodiments of the Constrained Predictive Interface. As summarized above, the Constrained Predictive Interface provides various techniques for applying predictive constraints on a source-channel predictive model to improve UI characteristics such as accuracy, usability, discoverability, etc. in a variety of source-channel based predictive user interfaces. The following sections provide a detailed discussion of the operation of various embodiments of the Constrained Predictive Interface, and of exemplary methods for implementing the program modules described in Section 1 with respect to FIG. 1.

In particular, the following sections provide examples and operational details of various embodiments of the Constrained Predictive Interface. This information includes: a discussion of common techniques for improving the accuracy of soft keyboards; source-channel model based approaches to input modeling; “effective hit targets” for use by the Constrained Predictive Interface; controlling the impact of user interface (UI) intelligence; predictive constraints for improving UI usability; constrained touch models; examples of specific touch models for soft or virtual keyboards or key/button-type interfaces; and the extension of the Constrained Predictive Interface to a variety of user interface types.

2.1 Improving the Accuracy of Soft Keyboards

As is known to those skilled in the art, typing accurately and quickly on a soft or virtual keyboard is generally an error prone process. This problem is especially evident when using relatively small mobile devices such as mobile phones. The reasons for this include the lack of haptic feedback (e.g., touch-typing is more difficult when the boundaries of the keys cannot be felt) and the small size of the keys with respect to the fingertips. Several intelligent keyboard technologies have been introduced to help alleviate such problems. These known technologies include:
1) Hit Target Resizing: Hit target resizing is a known technique whereby the region of the keyboard that returns a specific letter changes depending on context. For example, given that the user has already typed the letter “Q,” a finger touch in the boundary between the “I” and “U” keys will return a “U” because “U” is more likely than “I” following “Q.” That is, after typing a “Q,” the “hit target” for “U” expands while the “hit target” for “I” shrinks. Similarly, after the input “QU,” the hit target for “I” expands and the hit target for “U” shrinks because “I” is more likely after “QU” (as in “quick”) than “QUU”, so that a finger touch in the same place between “I” and “U” will be interpreted as an “I.”
2) Auto-Correction: Auto-correction is a known technique that automatically corrects errors in the text typed by the user. For example, if the user types “WE[DS]” where “[DS]” is ambiguous and may have been an “D” or an “S,” the keyboard might provisionally interpret this as “WED” and then correct this to “WES” if the next key presses are “T <space>” to give “WEST<space>.”
3) Prediction/Auto-Completion: Prediction and auto-completion are known techniques for facilitating user input by anticipating and completing text before the user has finished typing that text. For example, if the user touches the sequence “SURPRI” unambiguously, the completions “SURPRISE,” “SURPRISES,” “SURPRISING,” etc. are suggested.

As described in the following paragraphs, the Constrained Predictive Interface described herein builds on these known techniques for applying predictive constraints on the channel model in a source-channel predictive model to improve accuracy in a variety of source-channel based predictive user interfaces. Examples of such user interfaces include, but are not limited to, soft or virtual keyboards, pen interfaces, multi-touch interfaces, 3D gesture interfaces, myoelectric or EMG based interfaces, etc.

2.2 Source-Channel Approach to Input Modeling

In general, conventional source-channel based approaches to input modeling provide methods for improving the accuracy of user input systems such as soft keyboards. Such source-channel models generally use a first statistical model (e.g., a “source model” or a “language model”) to model the likelihood that users would type different sequences of keys in combination with a second statistical model (e.g., a “channel model” or “touch model”) that models the likelihood that a user touching different soft keys will generate different digitizer detection patterns. Note that for purposes of explanation regarding the use of soft or virtual keyboards, the following discussion will assume that the digitizer outputs an (x, y) coordinate pair for each touch. Further, these ideas can be extended to more elaborate digitizer outputs such as bounding boxes.

Language models assign a probability p_{L}(k₁, . . . , kₙ) to any sequence of keys, k₁, . . . , kₙ ∈ [symbol] . Typically, causal or left-to-right language models are used that allow this probability, p_{L}, to be efficiently computed in a left-to-right manner using Bayes' rule as p(k₁)p(k₂|k₁)p(k₃|k₁,k₂) . . . p(kₙ|k₁, . . . , kₙ₋₁). Often, an N-gram model where the approximation p_{L}(kᵢ|k₁, . . . ,kᵢ₋₁)≈p_{L}(kᵢ|k_{i-(N-1)}, . . . ,kᵢ₋₁) is used.

In contrast, a touch model assigns a probability p_{T}(x₁, . . . ,xₙ|k₁, . . . ,kₙ) to the digitizer generating the sequence of touch locations x₁, . . . ,xₙ ∈ [symbol] ⊂ [symbol] ² when the user types keys k₁, . . . ,kₙ. Typically an independence assumption is made to give p_{T}(x₁, . . . ,xₙ|k₁, . . . ,kₙ)≈Πᵢ₌₁ⁿp_{T}(xᵢ|kᵢ).

Given a language model and a touch model, hit target resizing is implemented by taking the keys typed so far k₁, . . . ,kₙ₋₁ and the touch location xₙ to decide what the nth key typed was, according to:

$${k}_{n} = {argmax}_{k} p ( k \vert {k}_{1} , … , {k}_{n - 1} , {x}_{n} ) \qquad Equation ( 1 )$$

which is given by

$${k}_{n} = {argmax}_{k} p ( k \vert {k}_{1} , … , {k}_{n - 1} ) p ( {x}_{n} \vert k ) . \qquad Equation ( 2 )$$

2.2.1 Hit-Target Resizing with Source-Channel Modeling

While conventional source-channel modeling does not explicitly resize the hit target, conventional source-channel modeling leads to implicit hit targets for each key in each context, consisting of the touch locations that return that key.

For example, automatic correction of hit targets can be done by done by examining the key presses or touches of the user with respect to the probability of each key, as illustrated by Equation (3):

(k₁, . . . ,kₙ)*=argmaxₖ_{₁}_{, . . . ,k}_{ₙ}p(k₁, . . . ,kₙ|x₁, . . . ,xₙ) Equation (3)

which is given by Equation (4), as follows:

(k₁, . . . ,kₙ)*=argmaxₖ_{₁}_{, . . . ,k}_{ₙ}p_{L}(k₁, . . . ,kₙ)p_{T}(x₁, . . . ,xₙ|k₁, . . . ,kₙ) Equation (4)

which can be efficiently computed using dynamic programming techniques.

2.2.2 Prediction/Auto-Completion with Source-Channel Modeling

In a source-channel modeling system, prediction/auto-completion can be done by as a function of the key sequences pressed, touched, or otherwise selected by the user in combination with the probability of each key or key sequence as illustrated by Equation (5), as follows:

(k₁, . . . ,kₘ)*=argmax_{m≧n}argmaxₖ_{₁}_{, . . . ,k}_{ₘ}p(k₁, . . . ,kₘ|x₁, . . . ,xₙ) Equation (5)

where kₘ is constrained to be a word separator (e.g., dash, space, etc.).

Because the problem is decomposed into a language model and a touch model, the language model can be estimated based on text data that was not necessarily entered into the target keyboard, and the touch model can be trained independently of the type of text a user is expected to type. Note that the source-channel approach described here is analogous to the approach used in speech recognition, optical character recognition, handwriting recognition, and machine translation. Thus, more sophisticated approaches such as topic sensitive language models, context sensitive channel models, and adaptation of both models can be used here. Further, the ability to specify the touch model and language model independently is critical. In practice, the language model may depend on application and input scope (e.g., specific language models for email addresses, URLs, body text, etc.), while the touch model may depend on the device dimensions, digitizer, and the keyboard layout.

2.3 Effective Hit Targets

For each of the three cases described in Section 2.2, including hit target resizing, auto-correction, and auto-completion, the Constrained Predictive Interface defines an “effective hit target,” [symbol] (c), for any particular key, k, of a soft or virtual keyboard given a context, c, as:

[symbol]

(c)={x ∈ χ π(k|c)p_{T}(x|k)≧π(k′|c)p_{T}(x|k′)∀k′ ∈ [symbol] } Equation (6)

The prior probability, π(k|c), of k in the context c may depend on the language model and the touch model depending on the information encoded in the context. In the case of hit target resizing, it includes all prior letters, and therefore is the language model probability of k given the keystroke history preceding the current user keystroke. Similarly, In the case of auto-correction, the prior probability, π(k|c), is the posterior probability of k given all previous and following touch locations, and depends on both the language and touch models. Note that for purposes of explanation, the following discussion will sometimes will leave the context implicit by referring to the effective hit target as simply [symbol] Note that “effective hit target” refers to the points on the keyboard where a specific key is returned, and not the key that the user intended to hit (i.e. the “target key”).

2.4 Controlling the Impact of UI Intelligence

While predictive models are useful for improving the accuracy of soft keyboards, overly strict predictive models can actually prevent the user from selecting particular keys, regardless of the user intent. Consequently, the user (or the operating system or application), may want to control the extent to which intelligent technologies impact the user experience. Reasons that the user may want to control the impact of the predictive model include cases where the predictive technology, being imperfect, does not match the behavior of a particular user in a particular context well, or because the predictive module is unable to determine the appropriate context for making predictions.

In various embodiments, this user (or automatic) control takes the form of a context weight, α, typically ranging between 0% and 100% (but can be within any desired range) for the source model, and typically ranging from 100% and larger for the channel model (but can be set within any desired range). Note that in various embodiments, either or both the source and channel model can be weighted using different context weights. However, it should be also noted while both the source and channel models can be weighted using the same context weights, this equates to the case where neither model is weighted since the common weights will simply cancel each other when determining the output of the source-channel model.

For example, given a context weight on the order of about of 0% on the source model (i.e., the language model in the case of a soft or virtual keyboard) there is little or no predictive intelligence for the source model, thus making the predictive intelligence of the channel model (i.e., the touch model in the case of a soft or virtual keyboard) as dominant as possible. However, the effective removal of the source model from the overall source-channel model in the case where the context weight on the source model is at or near 0% can sometimes cause problems where the user input returned by the source-channel model does not match the input expected by the user. This issue is addressed by the use of a “neutral source model” in place of the weighted source model for cases where the context weight on the source model is at or near 0% (i.e., when α≅0).

In particular, in the case of a soft or virtual keyboard a “neutral language model” (i.e., a “neutral source model”) is used to ensure that the hit targets for each key match the rendered keyboard. In the more general case, the use of a “neutral source model” ensures that actual user inputs directly correspond to “expected user input boundaries” with respect to predefined exemplary patterns or boundaries for specific inputs. Examples of expected user input boundaries for various UI types include rendered boundaries of keys for a soft or virtual keyboard, gestures or gesture angles within predefined exemplary gesture patterns in a gesture-based interface, speech patterns within predefined exemplary words or sound patterns in a speech-based interface, etc.

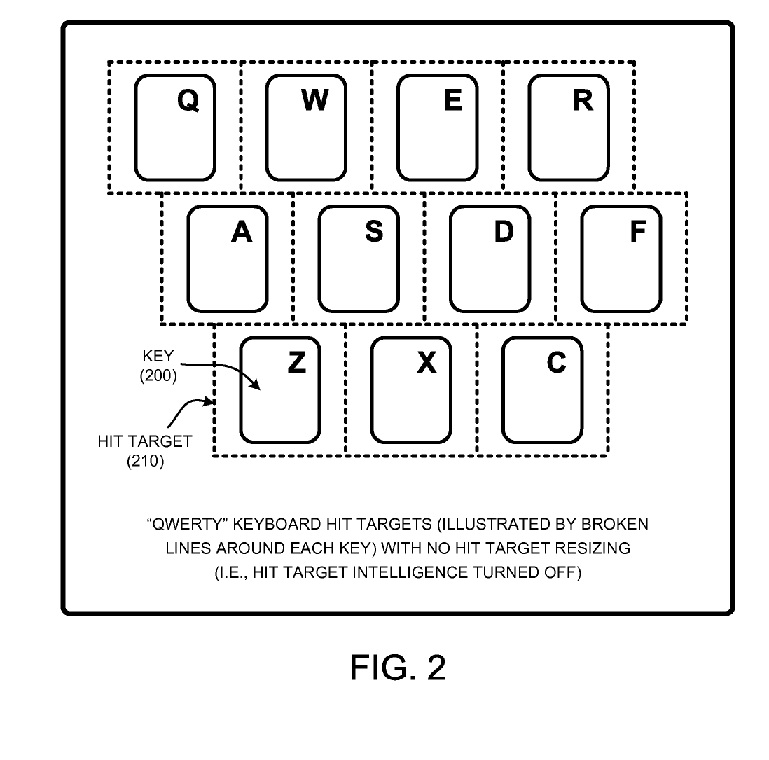

For example, in the case of a soft or virtual keyboard when weighting the source model, at or near 0%, the hit targets (e.g., region 210 inside broken line around key 200) should align with the rendered keyboard as shown in FIG. 2. However, to ensure that the hit targets actually align with the rendered keyboard in this case, the source model, having been weighted to the point where the probabilistic influence of the source model is negligible, is replaced with the aforementioned “neutral language model” (as described in further detail below). As noted above, for α≅0 (i.e., the context weight on the source model is set at or near 0%) this is the same result that would be obtained if little or no predictive technology were used in the soft or virtual keyboard for the corresponding language model. It should also be noted that by applying a sufficiently large context weight to the channel model, the predictive influence of the source model can be limited as if a context weight on the source model had been set at or near 0%. Thus, it should be understood that any discussion of setting the context weight on the source model to a value at or near 0% will also apply to cases where the context weight on the channel model is increased to a level sufficient to limit the predictive influence of the source model as if the context weight on the source model had been set to a value at or near 0%.

As noted above, it should be understood that the concept of using a neutral source model when the context weight applied to the source model is at or near 0% (i.e., α≅0) is extensible to any source-channel model based user interface. However, for purposes of explanation, the following discussion will explain the use of the “neutral language model” (i.e., the “neutral source model”) in the case of a soft or virtual keyboard.

In general, the hit targets should resize to reflect the effect of the predictive models as the weight on the source model approaches 100% (assuming an unweighted channel model). Intuitively, this would be similar to a language model weight commonly used in speech recognition or machine translation. However, the condition that the hit targets match the rendered keyboard when the context weight is at or near 0% (i.e., when α≅0) on the source model introduces a small complication. In particular, hit targets under the language model weight formulation are given by:

[symbol]

(c)={x ∈ χ π(k|c)^{α}p_{T}(x|k)≧π(k′|c)^{π}p_{T}(x|k′)∀k′ ∈ [symbol] } Equation (7)

When α=0, this reduces to:

[symbol]

(c)={x ∈ χ p_{T}(x|k)≧p_{T}(x|k′)∀k′ ∈ [symbol] } Equation (8)

The condition that these hit targets will match the rendered keyboard, when α≅0, imposes a very strong constraint on the touch model (i.e., the channel model in the more general case). In other words, when α≅0 it is useful for the hit target for each key to match the rendered keyboard without resizing those hit targets. One way to achieve this behavior without restricting the touch model further is to use a “neutral language model”, π₀(k), proportional to:

$${( \frac{π ( k \vert c )}{{π}_{0} ( k )} )}^{α} {π}_{0} ( k ) \qquad Equation ( 9 )$$

where π₀(k) is chosen so that the neutral targets, [symbol] (c), of each individual key:

[symbol]

(c)={x ∈ χ (π₀(k)p_{T}(x|k)≧π₀(k)p_{T}(x|k′)∀k′ ∈ [symbol] } Equation (10)

match the rendered keyboard. This is equivalent to allowing un-normalized touch models. Therefore, the selection of the touch model, p_{T}(x|k), includes the choice of neutral language model, π₀(k), that is selected such that the “neutral targets” (i.e., the hit targets corresponding to the use of the neutral language model) of the keys match the rendered keyboard.

Note that the variable a is referred herein as to as a “context weight” to distinguish it from a traditional language model weight. Further, it should also be noted that in various embodiments, the context weight is a function of one or more of a variety of factors such as typing speed, latency between keystrokes, the input scope, keyboard size, device properties, etc. that depend upon the particular type of UI being enabled by the Constrained Predictive Interface.

For example, in the case of a soft or virtual keyboard, as a user types faster (i.e., decreased key input latency), it is expected that the accuracy of the user finger placement will decrease. Consequently, increasing the context weight on the language model (or decreasing the context weight on the touch model) as a function of user typing speed or input latency will generally improve accuracy of the keys returned by the overall source-channel model. Conversely, as the typing speed or input latency decreases (thus indicating a more deliberate user finger placement), decreasing the context weight on the language model (or increasing the context weight on the touch model) as a function of user typing speed or input latency will generally improve accuracy of the keys returned by the overall source-channel model. Similarly, as the size of the keyboard decreases, such as with the input screen of a relatively small mobile phone, PDA, etc., it is more difficult for the user to accurately touch the intended keys since those keys may be quite small. Therefore, increasing the context weight on the source model (or decreasing the context weight on the touch model) as a function of decreasing keyboard size will also generally improve the accuracy of the keys returned by the overall source-channel model.

An expanded example of determining which model (i.e., the source model or the channel model) is to be weighted will now be presented. For example, if the user is typing quickly, then the language model (i.e., the source model) should be weighted more than the touch model (i.e., the channel model). Conversely, if the user is typing slowly, then the touch model should be weighted more. More specifically, if the user is entering keys quickly (i.e., short latencies between keys), it is likely that the user will make more finger positioning mistakes when attempting to hit particular keys. Note that this is true whether user is typing or using any other interface (e.g., gesture interfaces, myoelectric interfaces, etc., with short latencies between user inputs). Further, in view of the preceding discussion, it should be understood that decreasing the weight on the source model can achieve similar results to increasing the weight on the channel model, and vice versa.

Thus, in the case of short latencies between user inputs, it is generally desirable to weight the language model (i.e., the source model) more, under the implicit assumption that the overall system should be good enough to recognize what the user is attempting to input. Other the other hand, if the user is entering keys slowly, then the user is likely trying to be very deliberate about his input. In this situation, it is generally desirable to weight the weight the language model less (or the touch model more) since the user may be trying to enter something that he believes the overall system is not good enough to recognize. For example, if the quickly (and intentionally) types “knoesis”, and the system auto-corrects this word to something not intended, then the next time that the user types it, he will likely type “kno” quickly and then “e” not so quickly—because the user wants to get it right. In other words, given some or all of the various user contexts discussed above, such as input latency, for example, the Constrained Predictive Interface will determine which model to weight (i.e., source model or channel model) along with how much weight should be applied to the selected model. In addition, when the touch model is weighted highly (or the language model is weighted to a level at or near zero), a neutral language model can be used to ensure that the resulting hit targets match the rendered keyboard.

As noted above, in various embodiments of the Constrained Predictive Interface, the context weight is set automatically as a function of various factors, including typing speed, input latencies, the input scope, keyboard size, device properties, etc. However, in related embodiments, the context weights on either or both the source model and the channel model are set to any user-desired values. Such embodiments allow the user to control the influence of the predictive intelligence of the touch model (i.e., the channel model in the more general case) and/or the language model (i.e., the source model in the more general case). Further, the concept of neutral source models, as discussed above, are also applicable to embodiments including user adjustable context weights, with the neutral source model being either automatically applied based on the context weight, as discussed above, or manually selected by the user via a user interface.

2.5 Predictive Constraints for Improving UI Usability

Conventional source-channel models are sometimes considered “optimal” in the sense that as the language model gets closer and closer to modeling the true distribution of text entered into a device, and as the touch model gets closer and closer to the true distribution of digitizer output, the output of the soft keyboard approaches the optimal accuracy possible.

However, the shapes of the hit targets implicit in the language and touch models may be quite different from what a user intuitively expects. This may lead to a confusing user experience. Therefore, in various embodiments of the Constrained Predictive Interface, a priori constraints on the hit targets are specified in order to improve the user experience. In the case of soft or virtual keyboards, these a priori constraints include the concepts of “sweet spots” and “convex hit targets.”

2.5.1 Sweet Spots

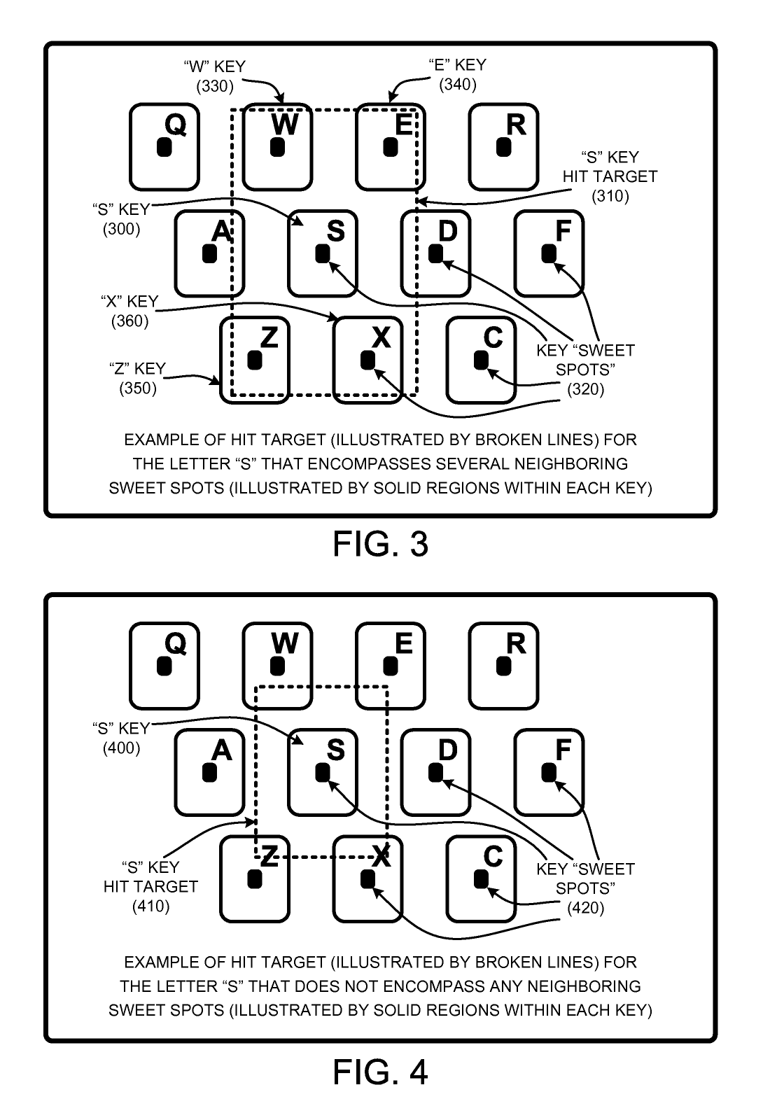

In various embodiments, one or more of the keys in the soft or virtual keyboard enabled by Constrained Predictive Interface includes a “sweet spot” in or near the center of each key that returns that key, regardless of the context. For example, the user touching the dead center of the “E” key after typing “SURPRI” should yield “SURPRIE,” even if “SURPRIS” is more likely. In other words, when using sweet spots, the hit target for a key is constrained such that it is prevented from growing to include the “sweet spot” of neighboring keys. This concept is illustrated by FIG. 3 and FIG. 4.

In particular, the problem of unconstrained hit targets is illustrated by FIG. 3, which shows a hit target 310 for the key “S” 300 which is expanded to cover most of the regions (including the sweet spots 320) for neighboring keys “W,” “E,” “Z,” and “X” (330, 340, 350 and 360, respectively). Consequently, in this case, it would be quite difficult if not impossible for the user to type the letters “W,” “E,” “Z,” and “X”.

In contrast, as illustrated by FIG. 4, constraining the hit target 410 of the “S” key 400 such that it does not cover the sweet spot 420 of any neighboring key ensures that the user can type or select these keys if they want to. However, given the expanded hit target 410 for the “S” key 400 the soft keyboard is biased towards returning an “S” rather than one of the neighboring keys.

In various embodiments, the sweet spot for each key is consistent in both size and placement for the various keys (i.e., approximately the same size in the approximate center of each key). However, in various embodiments, a user control is provided to increase or decrease the size of the sweet spots either on a global basis or for individual keys.

For example, assume that the user generally has repeated trouble accurately touching the sweet spot of the “Z” key when typing quickly, thereby leading to erroneous selection of the “A”, “S”, or “X” keys. In this case, the user can increase the size of the sweet spot of the “Z” key, or any other desired keys, via the user control to improve the overall user experience. Further, in related embodiments, the sweet spots of one or more of the keys are automatically increased or decreased in size, or automatically repositioned, to reflect learned user typing behavior (e.g., user typically hits on or near a particular coordinate when attempting to select the “Z” key). In addition, it should also be noted there are no particular constraints on the geometric shape of the sweet spot. In other words, each of the sweet spots can be any shape desired (e.g., square, round, amorphous, etc.).

2.5.2 Convet Hit Targets

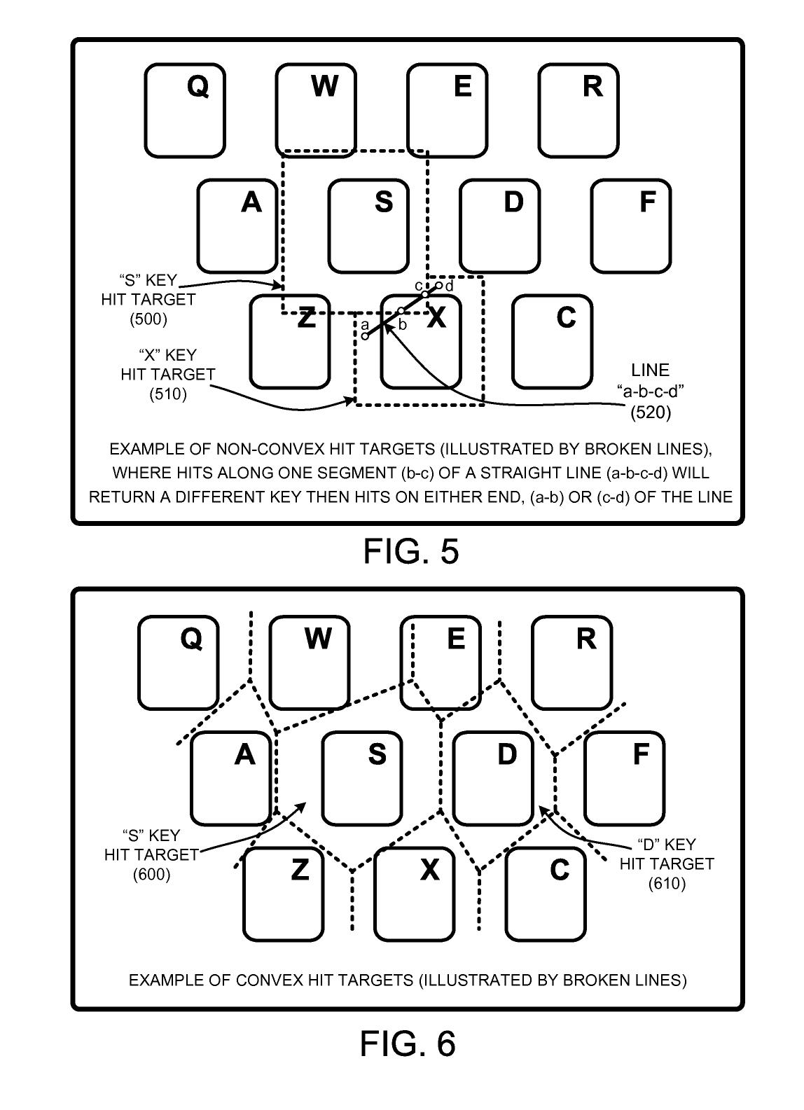

Another example of a confusing user experience results from the shape of conventional hit targets. For example, if in a particular context, the system returns the same key when the user touches either of two points on the keyboard, it is reasonable for the user to expect that the system will output the same key when the user touches any location between those two points, even if doing so leads to worse accuracy. However, as illustrated by FIG. 5, in the case of conventional hit target geometries, cases exist where the output will change from a first key, to a second key, then back to the first key while the user moves along a continuous straight-line path.

In particular, FIG. 5 illustrates the case where an “S” key hit target 500 and an “X” key hit target 510 are positioned such that when the user touches different points along a straight line, a-b-c-d (520), any point along segment a-b will return an “X”, any point along segment b-c will return an “S”, and any point along segment c-d will again return an “X”. In other words, the output will change from “X” to “S” and then back to “X” while the user moves her finger along the continuous straight line a-b-c-d (520). Clearly, such behavior can be confusing and non-intuitive to the user.

Therefore, in various embodiments, the Constrained Predictive Interface constrains the hit targets to take convex shapes. For example, as illustrated by FIG. 6, hit targets for the “S” and “D” keys, 600 and 610, respectively, are convex. The result is that while hit targets are allowed to grow or contract based on the probabilistic model, the shape of those hit targets is constrained to be a convex shape that inherently avoids the problem described above with respect to the use of conventional hit target geometries. In particular, unlike the problem illustrated by FIG. 5, the use of convex hit targets precludes any possible straight-line segment that can return a repeating key sequence such as X-S-X.

Clearly, a constraint such as convex hit targets can be especially helpful in a user interface where a tentative key response is shown to the user when they touch the keyboard. For example, the user can slide their finger around, with the tentative result changing as if they had touched the new current location instead of their original touch location. The response showing when the user releases their finger is selected as the final decision. This allows the user to search for the hit target of their desired key by sliding their finger across the soft keyboard without observing the confusing behavior of the conventional hit target geometries illustrated by FIG. 5.

2.6 Constrained Touch Models

In various embodiments, the Constrained Predictive Interface combines the usability constraints of “sweet spots” and “convex hit targets” described in Section 2.5 with source-channel type predictive models to provide an improved UI experience.

In particular, a set of allowable touch models is chosen so that either, or both, of the usability constraints discussed above (i.e., sweet spots and convex hit targets) are satisfied no matter what language model is chosen. However, in various embodiments, the language model is further constrained to be a “smooth” model. In other words, in embodiments employing a smooth language model, the language model allows any key to be hit or selected for any non-zero probability, regardless of the context. Given such a general language model, minimal constraints are imposed on the touch model such that the resulting hit targets obey either, or both, the sweet spot and convexity constraints described above. Note that the following notation is used throughout the following discussion:

[symbol] Alphabet of keys

χ ⊂ [symbol] ² Space of touch points

x,y,z ∈ χ Touch points

i,j,k ∈ [symbol] Keys, members of

[symbol]

[symbol] (c) ⊂ χ Hit target for i ∈ [symbol] in the context c.

[symbol] ⊂ χ Sweet spot for i ∈

[symbol]

[symbol] ⊂ χ Support of p_{T}(x|i)− [symbol] ={x ∈ χp_{T}(x|i)>0}

2.6.1 Guaranteeing the Sweet Spot Constraint

As discussed above, the sweet spot, [symbol] , for a particular key, [symbol] ᵢ, represents some fixed region in or near the center of that key that will return that key when the digitizer outputs an (x, y) coordinate pair within the boundaries of the corresponding sweet spot, regardless of the current context. Guaranteeing the sweet spot constraint in a system wherein hit targets have variable sizes based on probabilistic models uses a probabilistic modeling of the overall system. For example, consider Theorem 1, which states the following:

Theorem 1: Let [symbol] ⊂ [symbol] (c) ∀i ∈ [symbol] for any choice of context c and language model, and suppose that all sweet spots [symbol] have non-empty interiors. Then p_{T}( [symbol] |j)=0 ∀i ≠j. That is, [symbol] ∩ [symbol] =φ.

Proof of Theorem 1: For a proof by contradiction, suppose that there exist some i,j ∈ [symbol] with i≠j, such that p_{T}( [symbol] |j)=A>0. Since [symbol] ⊂ [symbol] (c), it can be seen that

p_{T}(x|i)π(i|c)>p_{T}(x|j)π(j|c) Equation (11)

for all x ∈ [symbol] for any choice of language model and context. Integrating both sides over [symbol] gives:

p_{T}( [symbol] |i)π(i|c)>p_{T}( [symbol] |j)π(j|c) Equation (12)

which gives:

$${p}_{T} ( {i}_{} \vert i ) > A \frac{π ( j \vert c )}{π ( i \vert c )} \qquad Equation ( 13 )$$

Since this relationship holds for any choice of language model and context, the relationship also holds when

$$\frac{π ( j \vert c )}{π ( i \vert c )} > \frac{1}{A} ,$$

yielding p_{T}( [symbol] |i)>1, which is a contradiction, thus proving Theorem 1.

Therefore, the touch model ensures that the sweet spot of any particular key can be hit or selected to as long as that the touch model assigns a zero (or very low) probability to any key generating touch points inside another key's sweet spot. Smooth distributions such as mixtures of Gaussians that are traditionally used for acoustic models in speech recognition are therefore inappropriate for use as touch models if the sweet spot constraint is used. Such distributions would have to have their support restricted and then renormalized in order to meet the sweet spot constraint. Indeed, this would hold for any other mixture distribution, such as mixtures of exponential distributions, or other mixtures of distributions of the form

p(x)∝e^{-||x-x}^{₀}^{||}^{^{p}} Equation (14)

where the norm ∥·∥ and the power p can be chosen arbitrarily as long as the distributions are normalized.

2.7 Touch Model Examples

The following paragraphs describe various examples of touch models that for are defined for use by the Constrained Predictive Interface for implementing soft or virtual keyboards and other key/button based UIs. In addition, the following examples include a discussion of the properties of the resulting hit targets.

2.7.1 Row-by-Row Touch Models

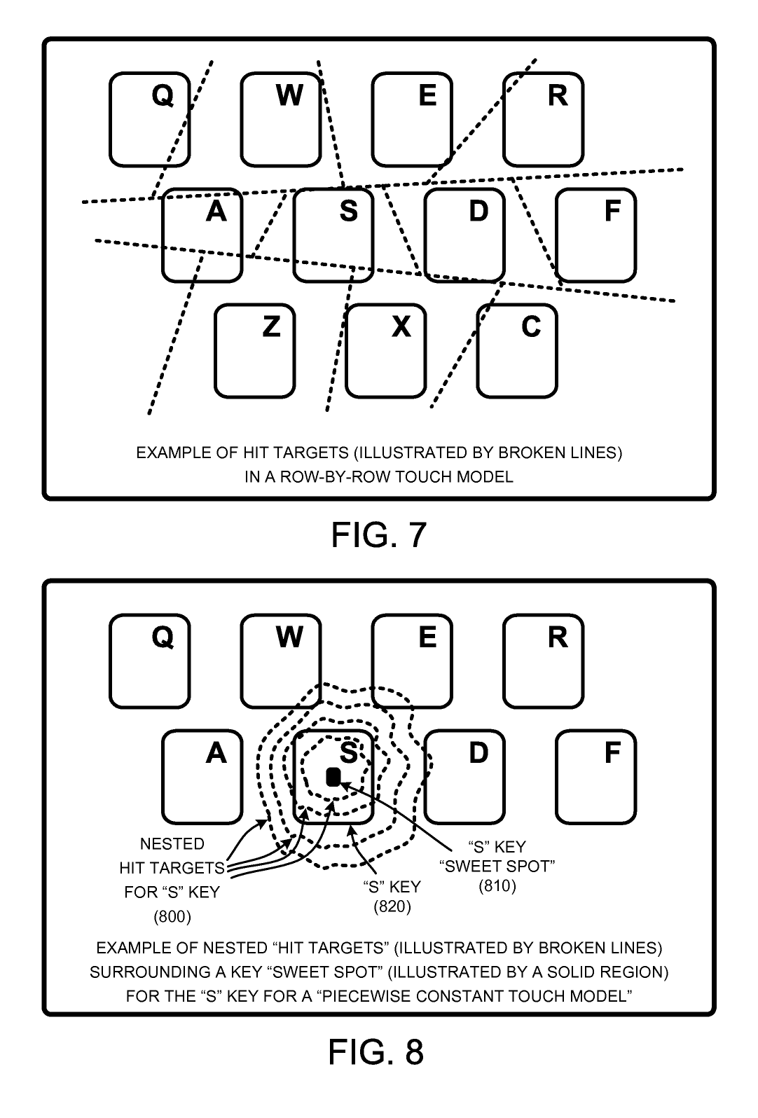

As illustrated by FIG. 7, a “row-by-row” touch model, p_{T}(x|i), is one that divides the keyboard (or other key/button based UI) into rows with straight (but not necessarily parallel lines), and then divides each row into targets using straight line segments. The touch models are chosen to assign probability only to points in one row. Hit targets are then resized by moving the line segments that segment a row into targets.

For example, in various embodiments, touch models can be defined to use a fixed, constant height for all keys in a keyboard row, and only allow resizing in the horizontal direction. Then, for each key, i, a support, [symbol] is defined as a rectangle of height hᵢ (where hᵢ is shared by all keys on i's row) and with left and right boundaries at horizontal coordinates lᵢ and rᵢ, and a sweet spot [symbol] ⊂ [symbol] so that [symbol] ∩ [symbol] =φ ∀j≠i. Then, by setting cᵢ to be key i's horizontal coordinate, choosing the touch model p_{T}(x|i) as illustrated by Equation (15) will simultaneously guarantee the sweet spot and convexity constraints of the touch model:

$${p}_{T} ( x \vert i ) = \{ \begin{matrix}0 & x ∉ {𝒫}_{i} \\ 2 \frac{1}{{h}_{i}} \frac{1}{{r}_{i} - {l}_{i}} \frac{x - {l}_{i}}{{c}_{i} - {l}_{i}} & {l}_{i} \leq {x}_{1} \leq {c}_{i} \\ 2 \frac{1}{{h}_{i}} \frac{1}{{r}_{i} - {l}_{i}} \frac{{r}_{i} - x}{{r}_{i} - x} & {c}_{i} \leq {x}_{1} \leq {r}_{i}\end{matrix} \qquad Equation ( 15 )$$

Given this formulation, the neutral language model, π₀(k), (as discussed in Section 2.4) is chosen so that the neutral targets match the rendered keyboard.

In particular, the following steps are repeated for each row of keys:
1. Assign an arbitrary weight to the leftmost key in the row.
2. Assign a weight to the next key such that the boundary between the target of the current and previous key matches the rendered keyboard.
3. Repeat Step 2 until weights are assigned to each key in the row.
4. Renormalize the weights on the row to 1/#(rows).

2.7.2 Piecewise Constant Touch Models

Given desired neutral targets [symbol] and sweet spots [symbol] for each key i, a “piecewise constant touch model”, p_{T}(x|i), for use in hit target resizing is specifically defined herein as a touch model having a set of Nᵢ>1 nested regions, where [symbol] ^{(N)} ⊂ [symbol] ^{(N-1)} ⊂ . . . ⊂ [symbol] ⁽¹⁾ with [symbol] ⁽ⁿ^{ᵢ}*⁾= [symbol] for some Nᵢ≧nᵢ*≧1 such that [symbol] ∩ [symbol] ⁽¹⁾=φ ∀j≠i. Values νᵢ^{(N)}>νᵢ^{(N-1)}>0 with νᵢ⁽ⁿ^{ᵢ}*⁾=1 are then assigned along with the following definitions:

nᵢ(x)=max{n: x ∈ [symbol] ⁽ⁿ⁾} Equation (16)

ƒᵢ(x)=νᵢ⁽ⁿ^{ᵢ}^{(x))} Equation (17)

Further, let wᵢ=∫ƒᵢ(x)dx, along with the following touch model definitions:

$$\begin{matrix}{p}_{T} ( x \vert i ) = \frac{1}{{w}_{i}} {f}_{i} ( x ) & Equation ( 18 ) \\ {π}_{0} ( i ) ∝ {w}_{i} & Equation ( 19 )\end{matrix}$$

The above-described formulation of a piecewise constant touch models yields hit targets which guarantee the sweet spot constraints and allows neutral targets to match the rendered targets. In other words, hit target expansion and contraction (i.e., hit target resizing) is defined by using the nested regions of the piecewise constant touch model as a function of the current probabilistic context of the user input. This concept of a “piecewise constant touch model”, as described above, is illustrated by FIG. 8, which shows an example of nested hit targets 800 (illustrated by broken lines) surrounding a key “sweet spot” 810 (illustrated by a solid region) for the “S” key 820.

2.7.3 Piecewise Constant Approximable Touch Models

In various embodiments, given a desired support (e.g., rectangle of height hᵢ, as described in Section 2.7.1), neutral target, and sweet spot for each key, a sequence of finer and finer grained piecewise constant touch models (as described in Section 2.7.2) are built whose nested regions and corresponding values are refined further and further, to approximate a continuous function. This approximated continuous function provides a “piecewise constant approximable touch model” for use in hit target resizing. In other words, the “piecewise constant approximable touch model”, as specifically defined herein, provides an approximation of a continuous function (representing a series of nested hit targets for each key) that is used to define a touch model that when used in combination with the neutral language model guarantees the sweet spot constraint and has the aforementioned neutral targets.

For example, a pyramidal piecewise constant approximable touch model, p_{T}(x|i), can be constructed as follows:

For each key i, given its rectangular desired neutral target [symbol] define a rectangular support, [symbol] and a sweet spot, [symbol] such that [symbol] ⊂ [symbol] ⊂ [symbol] and [symbol] ∩ [symbol] =φ ∀j≠i. Further, define ƒᵢ(x) to be a unique function that has the following properties:
1) ƒᵢ(x)=0 for x on the boundary of [symbol]
2) ƒᵢ(x)=1 for x on the boundary of [symbol] and
3) The γ-level sets of ƒᵢ(x), defined as {x: ƒᵢ(x)=γ)} are uniformly spaced nested rectangles having uniform properties. Note however, that the nested regions are not limited to rectangular regions, and that these nested regions can be any shape desired (e.g., square, round, amorphous, etc.).
   Let wᵢ=∫ƒᵢ(x)dx, and define the touch model as follows:

$$\begin{matrix}{p}_{T} ( x \vert i ) = \frac{1}{{w}_{i}} {f}_{i} ( x ) & Equation ( 20 ) \\ {π}_{0} ( i ) ∝ {w}_{i} . & Equation ( 21 )\end{matrix}$$

This touch model yields targets that guarantee the sweet spot constraints and allows neutral targets to match the rendered targets. In other words, a “piecewise constant approximable touch model”, as specifically defined herein, represent a series of nested versions of the piecewise constant touch models described in 2.7.2 for use in hit target expansion and contraction (i.e., hit target resizing).

2.8 Extension to Other Types of User Interfaces

While the discussion above has been presented for a predictive touch keyboard, the principle of using source-channel predictive models with usability constraints to improve UI characteristics such as accuracy, usability, discoverability, etc., is easily extensible to other types of predictive user interfaces. For example, other types of predictive user interfaces for which the Constrained Predictive Interface can improve UI characteristics include speech-based interfaces, handwriting-based interfaces, gesture based interfaces, key or button based interfaces, myoelectric or EMG sensor based interfaces, etc. Note that any or all of these interfaces can be embodied in a variety of devices, such as mobile phones, PDAs, digital picture frames, wall displays, Surface™ devices, computer monitors, televisions, tablet PCs, media players, remote control devices, etc.

Further, it should also be understood that any conventional tracking or position sensing technology corresponding to various user interface types can be used to implement various embodiments of the Constrained Predictive Interface. For example, in the case of a soft or virtual keyboard, a conventional touch-screen type display can be used to simultaneously render the keys and determine the (x, y) coordinates of the user touch. Related technologies include the user of laser-based or camera-based sensors to determine user finger positions relative to a soft or virtual keyboard. Further, such technologies are also adaptable to use in determine user hand or finger positions or motions in the case of a hand or finger-based gesture-based user interface.

In other words, it should be understood that conventional user interface technologies, including touch-screens, pressure sensors, laser sensors, optical sensors, etc., are applicable for use with the Constrained Predictive Interface by modifying those technologies to include the concept of the predictive constraints described herein for improving the UI characteristics of such interfaces.

2.8.1 Handwriting Based Interfaces

Many approaches for handwriting recognition exist, where a language model or source model is used to model the likelihood of different characters or words in a given context and a channel model is used to model the likelihood of different features of the pen strokes given a target word of character. If for example, a pen stroke pattern is ambiguous and could either be interpreted as an ‘a’ or an ‘o,’ the language model would be used to disambiguate. For example, if the preceding characters are “eleph” the pattern would be interpreted as an “a” (since “elephant” is the probable word) while if the preceding characters are “alligat” the pattern would be interpreted as an “o” (since “alligator” is the probable word). However, such a system would make it very difficult for a user to deliberately write “allegata.”

Therefore, to ensure that the user can write whatever characters she wants, the “sweet spot” techniques described above with respect to a soft or virtual keyboard are adapted to modify handwriting-based user interfaces to ensure that any character sequence can be input by the user, regardless of any word or character probability associated with the language model.

In particular, each letter or word is assigned one or more exemplary patterns that take the role of “sweet spots” for that letter or word. In contrast to the region-based sweet spots in or near the center of each key in a soft keyboard, a “sweet-spot” constraint in the context of a language model is any pattern within some fixed threshold of the exemplary patterns that is recognized as the corresponding letters or words, regardless of any word or character probability associated with the language model. Note however, that in various embodiments, conventional spell checks can subsequently be performed on the resulting text to allow the user to correct spelling errors, if desired.

2.8.2 Gesture Based Interfaces

In various embodiments, the “sweet spot” techniques described above with respect to a soft or virtual keyboard are adapted to modify gesture-based user interfaces (such as pen flicks, finger flicks, 3-D hand or body gestures, etc.) are adapted improve the accuracy of 2-D and/or 3-D gesture based interfaces.

In particular, the Constrained Predictive Interface is adapted for use in improving gesture-based user interfaces that allow the use of contextual models to get high recognition accuracy while still ensuring that each gesture is recognizable if carefully executed, relative to one or more exemplary gestures. For example, suppose a horizontal right to left finger flick means “delete” and a diagonal lower right to upper left flick means “previous page.” Suppose also that a source model models the probability of going to the previous page or deleting given the user context. For example, “delete” may be more likely after misspelling a word, while “previous page” may be more likely after a period of inactivity corresponding to reading.

Therefore, a “sweet spot” constraint in this instance would state that a flick from right to left within a couple of degrees to the horizontal would mean delete no matter the context, while a flick within 40-50 degrees would mean go back no matter the context. In other words, the sweet spot constraint in a gesture-based user interface ensures that any gesture within some fixed threshold of the exemplary gesture is recognized as the corresponding gesture, regardless of the context.

2.8.3 Key or Button Based Interfaces

These are interfaces where the user presses, points at, or otherwise interacts with a button, key or other control to make their selection. Clearly, as with the soft or virtual keyboards described above, the keys or buttons in this context are also soft or virtual (e.g., buttons or keys displayed on a touch screen). As with soft or virtual keyboards, the regions of the UI that correspond to the different UI actions would grow and shrink depending on user context, in a manner analogous to hit targets in a keyboard. Further, either or both sweet spot and shape constraints can be imposed on those buttons or keys.

2.8.4 Myoelectric or EMG Based Interfaces

Myoelectric signals are muscle-generated electrical signals that are typically captured using conventional Electromyography (EMG) sensors. As is known to those skilled in the art, myoelectric signals, or sequences of myoelectric signals, from muscle contractions can be used as inputs to a user interface for controlling a large variety of devices, including prosthetics, media players, appliances, etc. In other words, various UI actions are initiated by evaluating and mapping electrical signals resulting from particular user motions (e.g., hand or finger motions, wrist motions, arm motions, etc.) to cause the user interface to interact with various applications in the same manner as any other typical user interface receiving a user input.

As with the soft or virtual keyboards described above, a source model is used to model the likelihood of different UI actions given the context in combination with a channel model that models the EMG signals corresponding to different muscle generated electrical signals. In order to ensure that certain UI actions are possible in any context, exemplary EMG signals corresponding to each of these actions are recorded (typically, but not necessarily on a per-user basis). “Sweet spot” constraints are then imposed by specifying that EMG signals that are within some threshold of these exemplary signals in a feature space in which measured EMG signals are embedded will initiate the corresponding actions, regardless of the context of those UI actions.

3.0 Exemplary Operating Environments

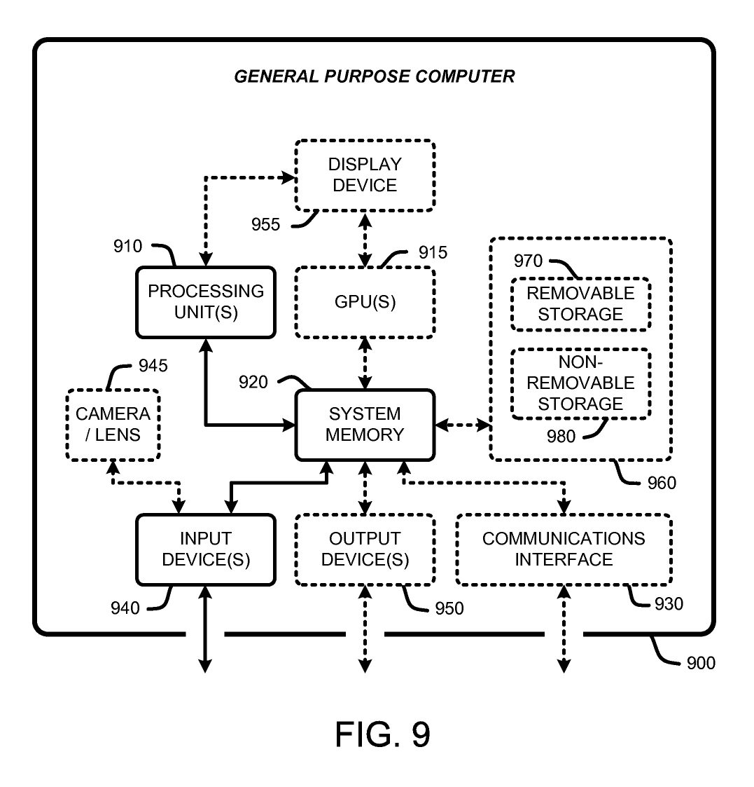

The Constrained Predictive Interface described herein is operational within numerous types of general purpose or special purpose computing system environments or configurations. FIG. 9 illustrates a simplified example of a general-purpose computer system on which various embodiments of the Constrained Predictive Interface, as described herein, may be implemented. It should be noted that any boxes that are represented by broken or dashed lines in FIG. 9 represent alternate embodiments of the simplified computing device, and that any or all of these alternate embodiments, as described below, may be used in combination with other alternate embodiments that are described throughout this document.

For example, FIG. 9 shows a general system diagram showing a simplified computing device. Such computing devices can be typically be found in devices having at least some minimum computational capability, including, but not limited to, hand-held computing devices, laptop or mobile computers, communications devices such as cell phones and PDA's, programmable consumer electronics, minicomputers, video media players, etc. To allow such devices to implement the Constrained Predictive Interface, the device should have some computational capability and in combination with the ability to receive user input from an integral or attached user input device, as described above.

In particular, as illustrated by FIG. 9, the computational capability is generally illustrated by one or more processing unit(s) 910, and may also include one or more GPUs 915. Note that that the processing unit(s) 910 of the general computing device of may be specialized microprocessors, such as a DSP, a VLIW, or other micro-controller, or can be conventional CPUs having one or more processing cores, including specialized GPU-based cores in a multi-core CPU.

In addition, the simplified computing device of FIG. 9 may also include other components, such as, for example, a communications interface 930. The simplified computing device of FIG. 9 may also include one or more conventional computer input devices 940 (either integral or attached via a wired or wireless connection), or other optional components, such as, for example, an integral or attached camera or lens 945. The simplified computing device of FIG. 9 may also include one or more conventional computer output devices 950.

The simplified computing device of FIG. 9 may also include storage 960 that is either removable 970 and/or non-removable 980. Note that typical communications interfaces 930, input devices 940, output devices 950, and storage devices 960 for general-purpose computers are well known to those skilled in the art, and will not be described in detail herein.

Finally, the simplified computing device 900 may also include in integral or attached display device 955. As discussed above, in various embodiments, this display device 955 also acts as a touch screen for accepting user input (such as in the case of a soft or virtual keyboard, for example).

The foregoing description of the Constrained Predictive Interface has been presented for the purposes of illustration and description. It is not intended to be exhaustive or to limit the claimed subject matter to the precise form disclosed. Many modifications and variations are possible in light of the above teaching. Further, it should be noted that any or all of the aforementioned alternate embodiments may be used in any combination desired to form additional hybrid embodiments of the Constrained Predictive Interface. It is intended that the scope of the invention be limited not by this detailed description, but rather by the claims appended hereto.

What is claimed is:

1. A computer-readable medium having computer executable instructions stored therein for implementing a predictive user interface, said instructions comprising:
a program module for receiving one or more user inputs from a user interface device;
a program module for probabilistically evaluating each user input to determine an intended user action corresponding to each user input as a probabilistic function of a current probabilistic user input context;
wherein the program module for probabilistically evaluating each user input comprises a source-channel model having one or more predictive constraints on the source-channel model;
wherein the predictive constraints limit the source-channel model by forcing specific user actions regardless of the current user input context when conditions corresponding to specific predictive constraints are met by the received user input; and
a program module for outputting the intended user action.

2. The computer-readable medium of claim 1 wherein the user input device is a soft keyboard.

3. The computer-readable medium of claim 2 wherein the soft keyboard is rendered on a touch-screen device.

4. The computer-readable medium of claim 2 wherein the predictive constraints comprise a “sweet spot” for one or more keys of the soft keyboard, each sweet spot being defined by a physical region within each corresponding key that causes the source-channel model to return that key, regardless of the current probabilistic user input context.

5. The computer-readable medium of claim 4 further comprising a program module for resizing hit targets for keys of the soft keyboard.

6. The computer-readable medium of claim 5 wherein the hit targets are defined using a “piecewise constant touch model” comprising one or more nested regions of hit targets for each key surrounding the sweet spot of each corresponding key.

7. The computer-readable medium of claim 5 wherein hit targets are defined using a “piecewise constant approximable touch model” comprising a series of one or more nested regions of hit targets for each key surrounding the sweet spot of each corresponding key.

8. The computer-readable medium of claim 1 further comprising a context weight that is automatically adjusted as a function of observed user input behaviors for limiting probabilistic influence of any component of the source-channel model.

9. The computer-readable medium of claim 1 further comprising the use of a “neutral source model” when a context weight on any component of the source-channel model is set to a value that reduces a predictive influence of a source model component of the source-channel model to a negligible level, and wherein the neutral source model ensures that user inputs correspond to expected user input boundaries.

10. The computer-readable medium of claim 1 wherein the user input device is a handwriting input device, and wherein the program module for probabilistically evaluating each user input determines intended user actions by recognizing specific handwritten characters corresponding user handwriting inputs.

11. The computer-readable medium of claim 1 wherein the user input device is a gesture input device, and wherein the program module for probabilistically evaluating each user input determines intended user actions by recognizing specific user gestures as inputs corresponding to the intended user actions.

12. The computer-readable medium of claim 1 wherein the user input device is a myoelectric signal capture device worn by the user, and wherein the program module for probabilistically evaluating each user input determines intended user actions by recognizing specific myoelectric signals as corresponding to the intended user actions.

13. A predictive user interface, comprising:
a user input device for receiving one or more user inputs;
a probabilistic source-channel model of the user input device;
a set of one or more predictive constraints for limiting a probabilistic influence of the source-channel model;
wherein the user inputs are evaluated by the source-channel model as limited by the predictive constraints to determine an intended user action corresponding to each user input; and
outputting each intended user action.

14. The predictive user interface of claim 13 wherein the predictive constraints limit the source-channel model by forcing specific user actions regardless of a current user input context when conditions corresponding to specific predictive constraints are met by the received user input.

15. The predictive user interface of claim 13 wherein the user input device is a virtual keyboard.

16. The predictive user interface of claim 15 wherein the predictive constraints comprise a “sweet spot” for each key of the soft keyboard, each sweet spot being defined by a physical region within each corresponding key that causes the source-channel model to return that key, regardless of any probabilistic user input context associated with the source-channel model.

17. The predictive user interface of claim 16 wherein variably sized hit targets for keys of the soft keyboard are defined using a probabilistic “piecewise constant touch model” comprising one or more nested regions of hit targets for each key surrounding the sweet spot of each corresponding key.

18. A system for receiving a user input for use in a computing device, comprising:
a user input device for receiving a user input;
a probabilistic source-channel model of the user input device;
a set of one or more predictive constraints for limiting a probabilistic influence of a channel model portion of the source-channel model;
a device for using the source-channel model to probabilistically evaluate the received user input to determine an intended user action corresponding to each user input as a probabilistic function of a current probabilistic user input context,
wherein the probabilistic evaluation of the received user input via the source-channel model is limited by one or more of the predictive constraints to force specific user actions regardless of the current user input context when conditions corresponding to specific predictive constraints are met by the received user input;
a device for applying an adjustable context weight for limiting probabilistic influence of any component of the source-channel model.
a device for outputting the intended user action.

19. The system of claim 18 wherein the user input device is a soft keyboard rendered on a touch-screen device, each rendered key of the soft keyboard having a resizable hit target representing a physical region in proximity to each key which enables either the corresponding key or a neighboring key to be selected based on the probabilistic evaluation of the received user input.

20. The system of claim 19 wherein the predictive constraints comprise a “sweet spot” for each key of the soft keyboard, each sweet spot being defined by a physical region within the boundaries of the hit targets corresponding to each rendered key of the soft keyboard that causes the source-channel model to return that key, regardless of the probabilistic evaluation of the received user input.
